(19) United States
(12) Patent Application Publication
(10) Pub. No.: US 2016/0190836 A1
(43) Pub. Date: Jun. 30, 2016

(54) METHOD AND APPARATUS FOR DETECTING VOLTAGE

(71) Applicant: Xiaomi Inc., Beijing (CN)

(72) Inventors: Wei Sun, Beijing (CN); Changyu Sun, Beijing (CN); Xiangdong Wang, Beijing (CN)

(21) Appl. No.: 14/856,568

(22) Filed: Sep. 17, 2015

Related U.S. Application Data
(63) Continuation of application No. PCT/CN2015/078107, filed on Apr. 30, 2015.

(30) Foreign Application Priority Data
Dec. 25, 2014 (CN) 2014108289768.0

(51) Int. Cl. H02J 7/00; G01R 31/36

(52) U.S. Cl. CPC H02J 7/0031; G01R 31/3696; G01R 31/362; H02J 7/0068; H02J 7/0081; H02J 2007/0037; H02J 2007/0039; H02J 2007/004

(57) ABSTRACT

The present disclosure relates to an apparatus and a method for detecting voltage of a battery and the battery thereof. The apparatus for detecting voltage includes: a voltage detection module, and an electric wire; wherein a segment of the electric wire is configured as a wire resistor, and detecting terminals of the voltage detection module are connected to two terminals of the wire resistor via measuring lines respectively.

### CROSS-REFERENCE TO RELATED APPLICATIONS

This application is a Continuation application of International Application No. PCT/CN2015/078107, filed with State Intellectual Property Office of P. R. China on Apr. 30, 2015, which is based upon and claims priority to Chinese Patent Application No. 2014108289768.0, filed on Dec. 25, 2014, the entire contents of which are incorporated herein by reference.

### TECHNICAL FIELD

The present disclosure relates to a field of circuit technology, and more particularly, to a method and apparatus for detecting voltage of a battery and the battery thereof.

### BACKGROUND

A power source protection circuit detects a voltage of a circuit, thereby determining whether to cut off the power source according to a detection result to protect the power source. Taking a power protection circuit in a battery as an example, in the related art, a protection integrated circuit (IC) in the power source protection circuit is connected to two terminals of a metal-oxide-semiconductor field-effect transistor (MOSFET) via measuring lines. The voltage of a battery cell is obtained by detecting a voltage between the two terminals of the MOSFET. The connection between the power source protection circuit and the battery cell if the detected battery voltage is abnormal.

However, due to the characteristics of MOSFET, during charging and discharging of the battery cell, the resistance of the MOSFET varies greatly with variations of voltage and temperature, so the detected voltage is not accurate enough, thus resulting in a poor protection of the power source.

### SUMMARY

According to a first aspect of embodiments of the present disclosure, there is provided an apparatus for detecting voltage, including: a voltage detection module and an electric wire. Herein, a segment of the electric wire is configured as a wire resistor, and detecting terminals of the voltage detection module are connected to two terminals of the wire resistor via measuring lines respectively.

According to a second aspect of embodiments of the present disclosure, there is provided a battery, including: a power source protection circuit and a battery cell. Herein, the power source protection circuit comprises a protection IC, a MOSFET connected with the protection IC via a switching control line and an electric wire having a first terminal connected with the MOSFET and a second terminal connected with the battery cell, the MOSFET is further configured for connecting with an external device. Herein, a segment of the electric wire is configured as a wire resistor, and detecting terminals of the protection IC are connected to two terminals of the wire resistor via measuring lines respectively.

According to a third aspect of embodiments of the present disclosure, there is provided a method for detecting voltage of the battery described above and including: detecting, via the protection IC with the measuring lines connected to the wire resistor, a battery voltage across the wire resistor; determining whether the battery voltage is within a predetermined voltage range; and controlling, via the MOSFET, to disconnect the connection between an external device and the battery cell if the battery voltage is not within the predetermined voltage range.

The apparatus for detecting voltage provided by embodiments of the present disclosure, by configuring the segment of the electric wire as the wire resistor, just enables the voltage detection module to detect the voltage over the wire resistor. Since the wire resistor itself is a part of the electric wire, the resistance thereof will not vary greatly with variations of voltage and temperature, so the wire resistor is relatively stable and thus the voltage detection accuracy is relatively high.

The voltage detection module in the apparatus for detecting voltage provided by embodiments of the present disclosure may be configured as the protection IC in the battery, or the coulometer specifically configured to obtain a current value by detecting voltage, and thus the voltage detection module can be used in various voltage detection scenarios.

If the voltage detection module in the apparatus for detecting voltage provided by embodiments of the present disclosure is the protection IC, the protection IC is connected with the MOSFET via the switching control line, and thus the switching of the MOSFET may be controlled by detecting the voltage over the wire resistor so as to protect the power source.

In the present disclosure, the length of the wire resistor may be determined according to the predetermined resistance of the wire resistor, the cross sectional area of the wire resistor and the resistivity of the wire resistor with the predetermined formula, and in an actual application, an appropriate length of the wire resistor may be obtained by testing, thereby satisfying the requirement of the voltage detection and improving the accuracy of voltage detection.

The battery and the method for detecting voltage applied in the battery, provided by embodiments of the present disclosure, by detecting the wire resistor in the electric wire with the power source protection circuit, may obtain an accurate voltage value and control the switching of the MOSFET by the voltage value, such that the battery cell can be well protected in charging or discharging of the battery cell.

It is to be understood that both the foregoing general description and the following detailed description are exemplary and explanatory only and are not restrictive of the disclosure, as claimed.

### BRIEF DESCRIPTION OF THE DRAWINGS

The accompanying drawings, which are incorporated in and constitute a part of this specification, illustrate embodiments consistent with the disclosure and, together with the description, serve to explain the principles of the disclosure.

FIG. 1 is a schematic diagram showing an apparatus for detecting voltage according to an exemplary embodiment;

FIG. 2 is a schematic diagram showing another apparatus for detecting voltage according to an exemplary embodiment;

FIG. 3 is a schematic diagram showing a battery according to an exemplary embodiment;

FIG. 4 is a flow chart showing a method for detecting voltage according to an exemplary embodiment.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the disclosure. Instead, they are merely examples of apparatuses and methods consistent with aspects related to the disclosure as recited in the appended claims.

Terms used in embodiments of the present disclosure are only intended for a description of a particular embodiment, but not for limitation of the present disclosure. “A/an”, “the” and “this” in a singular form used in the present disclosure and the attracted claims are also intended to include a plural form thereof, unless other meanings are indicated in the context clearly. It also should be understood that, the term “and/or” used herein means and includes any or all possible combinations of one or more listed items associated with each other.

It should be noted that, although terms such as “first”, “second” and “third” are used herein to describe various information, these information is not limited to these terms. These terms are only used to distinguish the information of a same type from each other. For example, the first information may also be called as the second information and similarly the second information may also be called as the first information without departing from the scope of the present disclosure. Depending on the context, the word “if” used herein may be interpreted as “at the moment that” or “when” or “in response to determining”.

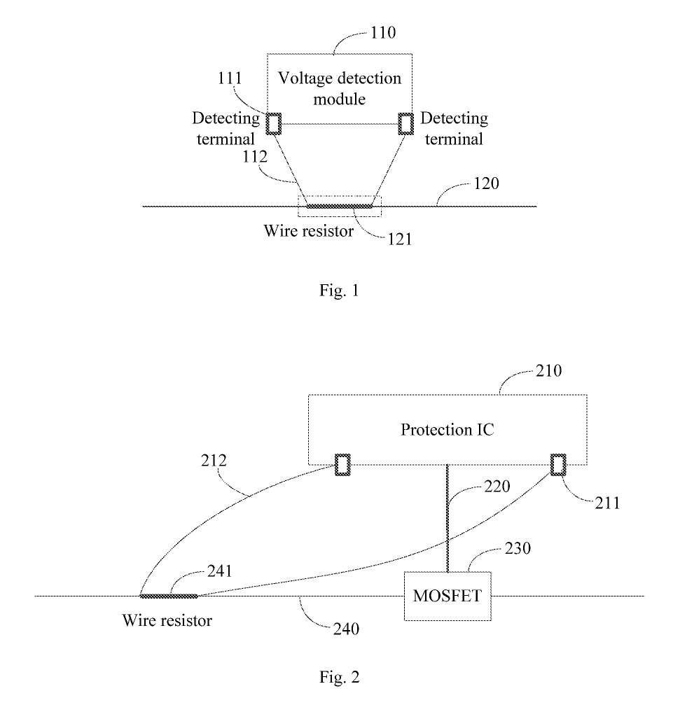

As shown in FIG. 1, the apparatus for detecting voltage according to an exemplary embodiment includes: a voltage detection module 110 and an electric wire 120.

In the embodiment, no specific circuit element, such as a detection resistor disposed specially or a metal-oxide-semiconductor field-effect transistor (MOSFET) disposed in the detection apparatus, is needed in order to detect the voltage. Instead, a segment of the electric wire 120 is configured as a wire resistor 121, and detecting terminals 111 of the voltage detection module 110 are connected with two terminals of the wire resistor 121 via measuring lines 112 respectively. Therefore, the voltage detection module 110 only needs to detect a voltage over the wire resistor 121. Since the wire resistor 121 is a part of the electric wire 121 itself, the resistance of the wire resistor 121 will not vary greatly with variations of voltage and temperature. In other words, the wire resistor 121 is relatively stable, and thus the voltage detection accuracy is relatively high. It should be noted that, the wire resistor 121 in FIG. 1 is represented by a bold line, but in actual applications, the thickness and width of the wire resistor 121 are same with those of other portions of the electric wire 120, and thus the wire resistor 121 represented by the bold line in FIG. 1 is intended solely for the purpose of clear illustration, and not intended to restrict the shape of the wire resistor 121.

In the embodiment, before configuration of the segment of the electric wire 120 to be the wire resistor 121, it is needed to predetermine the length of the wire resistor. The following formula may be used to determine the length of the wire resistor:

$$L = \frac{R \times S}{ρ} ,$$

where L represents the length of the wire resistor, R represents the resistance of the wire resistor, for example, an illustrative value of R is 10 mΩ (milliohm), S represents the cross sectional area of the wire resistor, when the electric wire 120 is determined the value of S may also be determined, and ρ represents the resistivity of the wire resistor which is a physical quantity representing the resistance property of a material. When the material of the wire resistor 120 is determined, the value of ρ is also determined. According to the above determined parameters, a theoretical value of L may be calculated, and the actual length of the wire resistor is further determined by testing based on the theoretical value of L. During the testing, it may be detected whether an actual value of the wire resistor is, for example, 10 mΩ when the length of the wire resistor is set to the theoretical value L. If the actual resistance of the wire resistor is less than 10 mΩ, the length of the wire resistor may be increased until the actual resistance of the wire resistor reaches 10 mΩ, and then a corresponding length of the wire resistor is determined as the actual length of the wire resistor. Based on the actual length of the wire resistor, the measuring lines 112 of the voltage detection module 110 are connected to the two terminals of the wire resistor 121 respectively.

In an embodiment, the voltage detection module 110 may be a protection integrated circuit (IC) in the battery, and the protection IC may be connected with the MOSFET via a switching control line. The electric wire 120 has a first terminal connected with the MOSFET and a second terminal connected with a battery cell. The MOSFET is further used for connecting with an external device (not shown). The external device may be a load when the battery is used to drive the load. The external device may also be a charging source when the battery is being charged. When detecting that the voltage over the wire resistor is not within a predetermined voltage range, the protection IC controls the MOSFET to disconnect the connection between the load and the battery cell via the switching control line, and thus the power source path can be well protected by controlling the switching of the MOSFET.

In another embodiment, the voltage detection module may be a coulometer configured to detect an electric quantity of battery. The coulometer is an instrument that detects increase or decrease of an accumulated electric quantity of the battery, and is configured to determine a residual electric quantity of a rechargeable battery and how long the battery can further continue supplying power in a particular operation condition, and is capable of estimating the electric quantity of the battery accurately. In the embodiment, the coulometer may obtain a voltage value by detecting the voltage over the wire resistor and calculate a current value according to the voltage value and the resistance of the wire resistor so as to measure the current accurately.

FIG. 2 is a schematic diagram showing another apparatus for detecting voltage according to an exemplary embodiment. The apparatus for detecting voltage may be specifically applied in a battery and it includes a protection IC 210, a switching control line 220, a MOSFET 230 and an electric wire 240.

The protection IC 210 is connected with the MOSFET 230 via the switching control line 220, and the electric wire 240 has a first terminal connected with the MOSFET 230 and a second terminal connected with a battery cell. In the embodiment, a segment of the electric wire 240 is configured as a wire resistor 241, and detecting terminals 211 of the protection IC 210 are connected respectively to two terminals of the wire resistor 241 via measuring lines 212. The MOSFET is further used for connecting with an external device (not shown). The external device may be a load when the battery is used to drive the load. The external device may also be a charging source when the battery is being charged. Therefore, the battery voltage can be obtained by the protection IC 210 by detecting a voltage between the two terminals of the wire resistor 241. Since the wire resistor 241 is a part of the electric wire 240 itself, a resistance thereof will not vary greatly with variations of voltage and temperature, so the wire resistor 241 is relatively stable and thus the voltage detection accuracy is relatively high. It should be noted that, the wire resistor 241 in FIG. 2 is represented by a bold line, but in actual applications, a thickness and width of the wire resistor 241 are same with those of other portions of the electric wire 240, and thus the wire resistor 241 represented by the bold line in FIG. 2 is intended solely for the purpose of clear illustration, and not intended to restrict the shape of the wire resistor 241.

In the embodiment, the protection IC 210 is a hardware circuit. When the measuring lines 212 of the protection IC 210 are connected to both sides of the wire resistor 241, the voltage over the wire resistor 241 can be measured in real time so as to obtain a circuit voltage. When detecting that the voltage over the wire resistor 241 is not within a predetermined voltage range, the protection IC 210 controls the MOSFET to disconnect the connection between the external device and the battery cell 230 via the switching control line 220. Therefore, in the embodiment, the switching of the MOSFET can be controlled by measuring the voltage over the wire resistor 241, thereby the power source path can be well protected.

It should be noted that, the number of MOSFET shown in FIG. 2 is exemplary only. In actual application, two or more MOSFETs may be used in combination in the circuit as a switch and two measuring lines of the protection IC are connected respectively with two sides of the combination of the two or more MOSFETs. In the embodiment, the method for determining the length of the wire resistor is same as the previous description for FIG. 1 and is thus omitted herein.

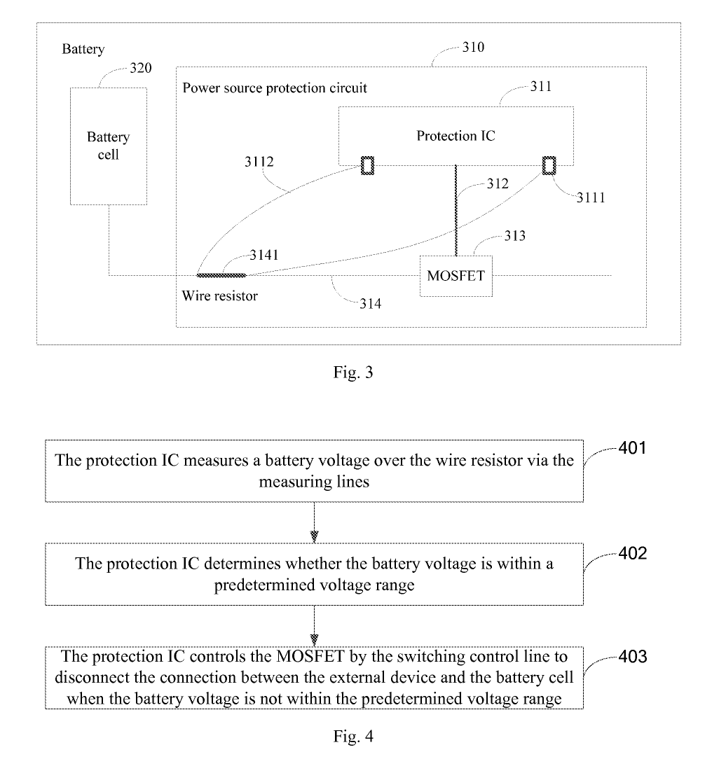

FIG. 3 is a schematic diagram showing a battery according to an exemplary embodiment.

In the embodiment, the battery generally refers to a rechargeable battery having charging and discharging functions. During the usage of the rechargeable battery, over charging, over discharging or over current may affect the life and performance of the battery, and thus it is needed to detect the interior voltage of the battery so as to prevent the battery being damaged. The battery according to the disclosure includes a power source protection circuit 310 and a battery cell 320. The power source protection circuit 310 is configured to detect the interior voltage of the battery. The battery cell 320 is the source for the battery capacity and is configured to store energy. In order to protect the battery cell 320, the power source protection circuit 310 measures the battery voltage and the battery current and disconnects the connection between an external device, such as a load or a charging source, and the battery cell 320 to protect the battery when the voltage or current is abnormal.

In the embodiment, the power source protection circuit 310 further includes: a protection IC 311, a MOSFET 313 connected with the protection IC 311 via a switching control line 312, and an electric wire 314 having a first terminal connected with the MOSFET 313 and a second terminal connected with the battery cell 320. The MOSFET is further used for connecting with an external device (not shown). The external device may be a load when the battery is used to drive the load. The external device may also be a charging source when the battery is being charged. A segment of the electric wire 314 is configured as a wire resistor 3141, and detecting terminals 3111 of the protection IC 311 are connected respectively to both terminals of the wire resistor 3141 via measuring lines 3112. The MOSFET 313 is controlled by the protection IC 311. When the protection IC 311 detects that the voltage or current is abnormal, the protection IC 311 controls the switching of the MOSFET 313 so as to enable or disable the connection between the external device and the battery cell.

When the power source protection circuit 310 detects the battery voltage in the embodiment, a process thereof is consistent with that of the apparatus for detecting voltage in FIG. 2 and is omitted herein.

Thus it can be seen from above embodiments, the battery provided by the embodiment obtains an accurate voltage value by measuring the wire resistor in the electric wire with the power source protection circuit and controls the switching of the MOSFET according to the voltage value, thereby well protecting the battery cell during the charging and discharging processes of the battery cell.

FIG. 4 is a flow chart showing a method for detecting voltage according to an exemplary embodiment, the method may be applied in the battery shown in FIG. 3. The method includes following steps.

In step 401, the protection IC measures a battery voltage over the wire resistor via the measuring lines.

With reference to FIG. 3, the measuring terminals of the protection IC are connected with the two terminals of the wire resistor by the measuring lines, and the protection IC is a hardware circuit and can measure a voltage over the wire resistor in real time so as to obtain the battery voltage.

In step 402, the protection IC determines whether the battery voltage is within a predetermined voltage range.

In the embodiment, an operation state of the battery mainly includes a charging state and a discharging state, and thus the predetermined voltage range may be defined by a highest voltage in the charging state and a lowest voltage in the discharging state.

In step 403, the protection IC controls the MOSFET by the switching control line to disconnect the connection between the external device and the battery cell when the battery voltage is not within the predetermined voltage range.

When the battery voltage is within the predetermined voltage range, the battery can be charged and discharged in normal and the protection IC controls the MOSFET to enable the connection between the load and the battery cell via the switching control line.

When the battery voltage is not within the predetermined voltage range, for an over charging state in which the battery voltage is larger than the highest voltage, the protection IC controls the MOSFET to disable the connection between the charging source and the battery cell via the switching control line so as to stop charging of battery cell. As to the over discharging state, i.e., the battery voltage is less than the lowest voltage, the protection IC controls the MOSFET to disable the connection between the load and the battery cell via the switching control line so as to stop the battery cell discharging to a load.

It can be seen from above embodiments, with the apparatus for detecting voltage provided by the embodiment, by measuring the wire resistor in the electric wire with the protection IC, an accurate voltage value can be obtained, and the switching of the MOSFET can be controlled according to the voltage value so as to protect the battery cell well in the charging and discharging processes of the battery cell.

Other embodiments of the disclosure will be apparent to those skilled in the art from consideration of the specification and practice of the disclosure disclosed here. This application is intended to cover any variations, uses, or adaptations of the disclosure following the general principles thereof and including such departures from the present disclosure as come within known or customary practice in the art. It is intended that the specification and examples be considered as exemplary only, with a true scope and spirit of the disclosure being indicated by the following claims.

It will be appreciated that the present disclosure is not limited to the exact construction that has been described above and illustrated in the accompanying drawings, and that various modifications and variations can be made without departing from the scope thereof. It is intended that the scope of the disclosure only be limited by the appended claims.

What is claimed is:

1. An apparatus for detecting voltage, comprising:
a voltage detection module, and
an electric wire;
wherein a segment of the electric wire is configured as a wire resistor, and detecting terminals of the voltage detection module are connected to two terminals of the wire resistor via measuring lines respectively.

2. The apparatus according to claim 1, wherein the voltage detection module comprises a protection integrated circuit (IC) or a coulometer.

3. The apparatus according to claim 2, wherein if the voltage detection module is the protection IC, the apparatus further comprises a switching control line and a metal-oxide-semiconductor field-effect transistor (MOSFET), and the protection IC is connected to the MOSFET via the switching control line; and
a first terminal of the electric wire is connected to the MOSFET and a second terminal of the electric wire is configured for connecting with a battery cell.

4. The apparatus according to claim 3, wherein the MOSFET is further configured for connecting with an external device, and the protection IC is configured to control the MOSFET to disconnect the connection between an external device and the battery cell via the switching control line if it detects that a voltage across the wire resistor is not within a predetermined voltage range.

5. The apparatus according to claim 1, wherein a length of the wire resistor satisfies the following formula
$$L = \frac{R \times S}{ρ} ,$$
wherein L represents a length of the wire resistor, R represents a resistance of the wire resistor, S represents a cross sectional area of the wire resistor, and ρ represents a resistivity of the wire resistor.

6. The apparatus according to claim 5, wherein a predetermined resistance of the wire resistor is 10 milliohms.

7. The apparatus according to claim 2, wherein a length of the wire resistor satisfies the following formula
$$L = \frac{R \times S}{ρ} ,$$
wherein L represents a length of the wire resistor, R represents a resistance of the wire resistor, S represents a cross sectional area of the wire resistor, and ρ represents a resistivity of the wire resistor.

8. The apparatus according to claim 7, wherein a predetermined resistance of the wire resistor is 10 milliohms.

9. The apparatus according to claim 3, wherein a length of the wire resistor satisfies the following formula
$$L = \frac{R \times S}{ρ} ,$$
wherein L represents a length of the wire resistor, R represents a resistance of the wire resistor, S represents a cross sectional area of the wire resistor, and ρ represents a resistivity of the wire resistor.

10. The apparatus according to claim 9, wherein a predetermined resistance of the wire resistor is 10 milliohms.

11. The apparatus according to claim 4, wherein a length of the wire resistor satisfies the following formula
$$L = \frac{R \times S}{ρ} ,$$
wherein L represents a length of the wire resistor, R represents a resistance of the wire resistor, S represents a cross sectional area of the wire resistor, and ρ represents a resistivity of the wire resistor.

12. The apparatus according to claim 11, wherein a predetermined resistance of the wire resistor is 10 milliohms.

13. A battery, comprising:
a power source protection circuit; and
a battery cell,
wherein the power source protection circuit comprises a protection IC, a MOSFET connected to the protection IC via a switching control line and an electric wire having a first terminal connected to the MOSFET and a second terminal connected to the battery cell, the MOSFET being further configured for connecting with an external device;
wherein a segment of the electric wire is configured as a wire resistor, and detecting terminals of the protection IC are connected to two terminals of the wire resistor via measuring lines respectively.

14. The battery according to claim 13, wherein a length of the wire resistor satisfies the following formula
$$L = \frac{R \times S}{ρ} ,$$
where L represents a length of the wire resistor, R represents a resistance of the wire resistor, S represents a cross sectional area of the wire resistor, and ρ represents a resistivity of the wire resistor.

15. The battery according to claim 14, wherein a predetermined resistance of the wire resistor is 10 milliohms.

16. A method for detecting voltage of the battery according to claim 13, the method comprising:
detecting, via the protection IC with the measuring lines connected to the wire resistor, a battery voltage across the wire resistor;
determining whether the battery voltage is within a predetermined voltage range; and
controlling, via the MOSFET, to disconnect the connection between an external device and the battery cell if the battery voltage is not within the predetermined voltage range.

17. The method according to claim 16, wherein a length of the wire resistor satisfies the following formula
$$L = \frac{R \times S}{ρ} ,$$
where L represents a length of the wire resistor, R represents a resistance of the wire resistor, S represents a cross sectional area of the wire resistor, and ρ represents a resistivity of the wire resistor.

18. The method according to claim 17, wherein a predetermined resistance of the wire resistor is 10 milliohms.
